(19) United States
(12) Patent Application Publication
(10) Pub. No.: US 2025/0141966 A1
(43) Pub. Date: May 1, 2025

(54) VEHICLE MAINTENANCE SYSTEM WITH DYNAMIC NETWORK

(71) Applicant: Midtronics, Inc., Willowbrook, IL (US)

(72) Inventor: Mohammed H. Petiwala, Buffalo Grove, IL (US)

(21) Appl. No.: 18/930,713

(22) Filed: Oct. 29, 2024

Related U.S. Application Data
(60) Provisional application No. 63/594,195, filed on Oct. 30, 2023.

(51) Int. Cl. H04L 67/12; G01R 31/385; G07C 5/00

(52) U.S. Cl. CPC H04L 67/12; G01R 31/385; G07C 5/008; G07C 2205/02

(57) ABSTRACT

A plurality of automotive tools each of which includes communication circuitry which provides communication between at least another tool in the plurality of tools, cluster forming circuitry configured to form a cluster comprises at least two tools in the plurality of tools, and data sharing circuitry configured to share data between the at least two tools in the cluster.

### CROSS-REFERENCE TO RELATED APPLICATION

The present application is based on and claims the benefit of U.S. provisional patent application Ser. No. 63/594,195, filed Oct. 30, 2023, the contents of which are hereby incorporated by reference in their entirety.

### BACKGROUND

Various types of vehicle maintenance devices are known in the art and have widespread uses. One use of such maintenance devices is for vehicle inspections. For example, a vehicle emission inspection can be performed to ensure the vehicle meets any emission requirements in a particular region. A vehicle safety inspection is another example and may be employed on vehicles using an internal combustion engine as well as electric vehicles.

The vehicle inspections are typically performed using one or more independent maintenance devices. An operator tests the vehicle using the various maintenance devices and records the result in order to determine if the vehicle has passed the inspection requirements.

Various techniques have been pioneered by Dr. Keith S. Champlin and Midtronics, Inc. of Willowbrook, Ill. for performing maintenance on vehicles and batteries. These techniques are described in a number of United States patents, for example, U.S. Pat. No. 3,873,911, issued Mar. 25, 1975, to Champlin; U.S. Pat. No. 3,909,708, issued Sep. 30, 1975, to Champlin; U.S. Pat. No. 4,816,768, issued Mar. 28, 1989, to Champlin; U.S. Pat. No. 4,825,170, issued Apr. 25, 1989, to Champlin; U.S. Pat. No. 4,881,038, issued Nov. 14, 1989, to Champlin; U.S. Pat. No. 4,912,416, issued Mar. 27, 1990, to Champlin; U.S. Pat. No. 5,140,269, issued Aug. 18, 1992, to Champlin; U.S. Pat. No. 5,343,380, issued Aug. 30, 1994; U.S. Patent No. 5,572, 136, issued Nov. 5, 1996; U.S. Pat. No. 5,574,355, issued Nov. 12, 1996; U.S. Pat. No. 5,583,416, issued Dec. 10, 1996; U.S. Pat. No. 5,585,728, issued Dec. 17, 1996; U.S. Pat. No. 5,589,757, issued Dec. 31, 1996; U.S. Pat. No. 5,592,093, issued Jan. 7, 1997; U.S. Pat. No. 5,598,098, issued Jan. 28, 1997; U.S. Pat. No. 5,656,920, issued Aug. 12, 1997; U.S. Pat. No. 5,757,192, issued May 26, 1998; U.S. Pat. No. 5,821,756, issued Oct. 13, 1998; U.S. Pat. No. 5,831,435, issued Nov. 3, 1998; U.S. Pat. No. 5,871,858, issued Feb. 16, 1999; U.S. Pat. No. 5,914,605, issued Jun. 22, 1999; U.S. Pat. No. 5,945,829, issued Aug. 31, 1999; U.S. Pat. No. 6,002,238, issued Dec. 14, 1999; U.S. Pat. No. 6,037,751, issued Mar. 14, 2000; U.S. Pat. No. 6,037,777, issued Mar. 14, 2000; U.S. Pat. No. 6,051,976, issued Apr. 18, 2000; U.S. Pat. No. 6,081,098, issued Jun. 27, 2000; U.S. Pat. No. 6,091,245, issued Jul. 18, 2000; U.S. Pat. No. 6,104,167, issued Aug. 15, 2000; U.S. Pat. No. 6,137,269, issued Oct. 24, 2000; U.S. Pat. No. 6,163,156, issued Dec. 19, 2000; U.S. Pat. No. 6,172,483, issued Jan. 9, 2001; U.S. Pat. No. 6,172,505, issued Jan. 9, 2001; U.S. Pat. No. 6,222,369, issued Apr. 24, 2001; U.S. Pat. No. 6,225,808, issued May 1, 2001; U.S. Pat. No. 6,249,124, issued Jun. 19, 2001; U.S. Pat. No. 6,259,254, issued Jul. 10, 2001; U.S. Pat. No. 6,262,563, issued Jul. 17, 2001; U.S. Pat. No. 6,294,896, issued Sep. 25, 2001; U.S. Pat. No. 6,294,897, issued Sep. 25, 2001; U.S. Pat. No. 6,304,087, issued Oct. 16, 2001; U.S. Pat. No. 6,310,481, issued Oct. 30, 2001; U.S. Pat. No. 6,313,607, issued Nov. 6, 2001; U.S. Pat. No. 6,313,608, issued Nov. 6, 2001; U.S. Pat. No. 6,316,914, issued Nov. 13, 2001; U.S. Pat. No. 6,323,650, issued Nov. 27, 2001; U.S. Pat. No. 6,329,793, issued Dec. 11, 2001; U.S. Pat. No. 6,331,762, issued Dec. 18, 2001; U.S. Pat. No. 6,332,113, issued Dec. 18, 2001; U.S. Pat. No. 6,351,102, issued Feb. 26, 2002; U.S. Pat. No. 6,359,441, issued Mar. 19, 2002; U.S. Pat. No. 6,363,303, issued Mar. 26, 2002; U.S. Pat. No. 6,377,031, issued Apr. 23, 2002; U.S. Pat. No. 6,392,414, issued May 21, 2002; U.S. Pat. No. 6,417,669, issued Jul. 9, 2002; U.S. Pat. No. 6,424,158, issued Jul. 23, 2002; U.S. Pat. No. 6,441,585, issued Aug. 17, 2002; U.S. Pat. No. 6,437,957, issued Aug. 20, 2002; U.S. Pat. No. 6,445,158, issued Sep. 3, 2002; U.S. Pat. No. 6,456,045; U.S. Pat. No. 6,466,025, issued Oct. 15, 2002; U.S. Pat. No. 6,465,908, issued Oct. 15, 2002; U.S. Pat. No. 6,466,026, issued Oct. 15, 2002; U.S. Pat. No. 6,469,511, issued Nov. 22, 2002; U.S. Pat. No. 6,495,990, issued Dec. 17, 2002; U.S. Pat. No. 6,497,209, issued Dec. 24, 2002; U.S. Pat. No. 6,507,196, issued Jan. 14, 2003; U.S. Pat. No. 6,534,993; issued Mar. 18, 2003; U.S. Pat. No. 6,544,078, issued Apr. 8, 2003; U.S. Pat. No. 6,556,019, issued Apr. 29, 2003; U.S. Pat. No. 6,566,883, issued May 20, 2003; U.S. Pat. No. 6,586,941, issued Jul. 1, 2003; U.S. Pat. No. 6,597,150, issued Jul. 22, 2003; U.S. Pat. No. 6,621,272, issued Sep. 16, 2003; U.S. Pat. No. 6,623,314, issued Sep. 23, 2003; U.S. Pat. No. 6,633,165, issued Oct. 14, 2003; U.S. Pat. No. 6,635,974, issued Oct. 21, 2003; U.S. Pat. No. 6,696,819, issued Feb. 24, 20144; U.S. Pat. No. 6,707,303, issued Mar. 16, 2004; U.S. Pat. No. 6,737,831, issued May 18, 2004; U.S. Pat. No. 6,744,149, issued Jun. 1, 2004; U.S. Pat. No. 6,759,849, issued Jul. 6, 2004; U.S. Pat. No. 6,781,382, issued Aug. 24, 2004; U.S. Pat. No. 6,788,025, filed Sep. 7, 2004; U.S. Pat. No. 6,795,782, issued Sep. 21, 2004; U.S. Pat. No. 6,805,090, filed Oct. 19, 2004; U.S. Pat. No. 6,806,716, filed Oct. 19, 2004; U.S. Pat. No. 6,850,037, filed Feb. 1, 2005; U.S. Pat. No. 6,850,037, issued Feb. 1, 2005; U.S. Pat. No. 6,871,151, issued Mar. 22, 2005; U.S. Pat. No. 6,885,195, issued Apr. 26, 2005; U.S. Pat. No. 6,888,468, issued May 3, 2005; U.S. Pat. No. 6,891,378, issued May 10, 2005; U.S. Pat. No. 6,906,522, issued Jun. 14, 2005; U.S. Pat. No. 6,906,523, issued Jun. 14, 2005; U.S. Pat. No. 6,909,287, issued Jun. 21, 2005; U.S. Pat. No. 6,914,413, issued Jul. 5, 2005; U.S. Pat. No. 6,913,483, issued Jul. 5, 2005; U.S. Pat. No. 6,930,485, issued Aug. 16, 2005; U.S. Pat. No. 6,933,727, issued Aug. 23, 200; U.S. Pat. No. 6,941,234, filed Sep. 6, 2005; U.S. Pat. No. 6,967,484, issued Nov. 22, 2005; U.S. Pat. No. 6,998,847, issued Feb. 14, 2006; U.S. Pat. No. 7,003,410, issued Feb. 21, 2006; U.S. Pat. No. 7,003,411, issued Feb. 21, 2006; U.S. Pat. No. 7,012,433, issued Mar. 14, 2006; U.S. Pat. No. 7,015,674, issued Mar. 21, 2006; U.S. Pat. No. 7,034,541, issued Apr. 25, 2006; U.S. Pat. No. 7,039,533, issued May 2, 2006; U.S. Pat. No. 7,058,525, issued Jun. 6, 2006; U.S. Pat. No. 7,081,755, issued Jul. 25, 2006; U.S. Pat. No. 7,106,070, issued Sep. 12, 2006; U.S. Pat. No. 7,116,109, issued Oct. 3, 2006; U.S. Pat. No. 7,119,686, issued Oct. 10, 2006; and U.S. Pat. No. 7,126,341, issued Oct. 24, 2006; U.S. Pat. No. 7,154,276, issued Dec. 26, 2006; U.S. Pat. No. 7,198,510, issued Apr. 3, 2007; U.S. Pat. No. 7,363,175, issued Apr. 22, 2008; U.S. Pat. No. 7,208,914, issued Apr. 24, 2007; U.S. Pat. No. 7,246,015, issued Jul. 17, 2007; U.S. Pat. No. 7,295,936, issued Nov. 13, 2007; U.S. Pat. No. 7,319,304, issued Jan. 15, 2008; U.S. Pat. No. 7,363,175, issued Apr. 22, 2008; U.S. Patent No. 7,398, 176, issued Jul. 8, 2008; U.S. Pat. No. 7,408,358, issued Aug. 5, 2008; U.S. Pat. No. 7,425,833, issued Sep. 16, 2008; U.S. Pat. No. 7,446,536, issued Nov. 4, 2008; U.S. Pat. No. 7,479,763, issued Jan. 20, 2009; U.S. Pat. No. 7,498,767, issued Mar. 3, 2009; U.S. Pat. No. 7,501,795, issued Mar. 10, 2009; U.S. Pat. No. 7,505,856, issued Mar. 17, 2009; U.S. Pat. No. 7,545,146, issued Jun. 9, 2009; U.S. Pat. No. 7,557,586, issued Jul. 7, 2009; U.S. Pat. No. 7,595,643, issued Sep. 29, 2009; U.S. Pat. No. 7,598,699, issued Oct. 6, 2009; U.S. Pat. No. 7,598,744, issued Oct. 6, 2009; U.S. Pat. No. 7,598,743, issued Oct. 6, 2009; U.S. Pat. No. 7,619,417, issued Nov. 17, 2009; U.S. Pat. No. 7,642,786, issued Jan. 5, 2010; U.S. Pat. No. 7,642,787, issued Jan. 5, 2010; U.S. Pat. No. 7,656,162, issued Feb. 2, 2010; U.S. Pat. No. 7,688,074, issued Mar. 30, 2010; U.S. Pat. No. 7,705,602, issued Apr. 27, 2010; U.S. Pat. No. 7,706,992, issued Apr. 27, 2010; U.S. Pat. No. 7,710,119, issued May 4, 2010; U.S. Pat. No. 7,723,993, issued May 25, 2010; U.S. Pat. No. 7,728,597, issued Jun. 1, 2010; U.S. Pat. No. 7,772,850, issued Aug. 10, 2010; U.S. Pat. No. 7,774,151, issued Aug. 10, 2010; U.S. Pat. No. 7,777,612, issued Aug. 17, 2010; U.S. Pat. No. 7,791,348, issued Sep. 7, 2010; U.S. Pat. No. 7,808,375, issued Oct. 5, 2010; U.S. Pat. No. 7,924,015, issued Apr. 12, 2011; U.S. Pat. No. 7,940,053, issued May 10, 2011; U.S. Pat. No. 7,940,052, issued May 10, 2011; U.S. Pat. No. 7,959,476, issued Jun. 14, 2011; U.S. Pat. No. 7,977,914, issued Jul. 12, 2011; U.S. Pat. No. 7,999,505, issued Aug. 16, 2011; U.S. Pat. No. D643,759, issued Aug. 23, 2011; U.S. Pat. No. 8,164,343, issued Apr. 24, 2012; U.S. Pat. No. 8,198,900, issued Jun. 12, 2012; U.S. Pat. No. 8,203,345, issued Jun. 19, 2012; U.S. Pat. No. 8,237,448, issued Aug. 7, 2012; U.S. Pat. No. 8,306,690, issued Nov. 6, 2012; U.S. Pat. No. 8,344,685, issued Jan. 1, 2013; U.S. Pat. No. 8,436,619, issued May 7, 2013; U.S. Pat. No. 8,442,877, issued May 14, 2013; U.S. Pat. No. 8,493,022, issued Jul. 23, 2013; U.S. Pat. No. D687,727, issued Aug. 13, 2013; U.S. Pat. No. 8,513,949, issued Aug. 20, 2013; U.S. Pat. No. 8,674,654, issued Mar. 18, 2014; U.S. Pat. No. 8,674,711, issued Mar. 18, 2014; U.S. Pat. No. 8,704,483, issued Apr. 22, 2014; U.S. Pat. No. 8,738,309, issued May 27, 2014; U.S. Pat. No. 8,754,653, issued Jun. 17, 2014; U.S. Pat. No. 8,872,516, issued Oct. 28, 2014; U.S. Pat. No. 8,872,517, issued Oct. 28, 2014; U.S. Pat. No. 8,958,998, issued Feb. 17, 2015; U.S. Pat. No. 8,963,550, issued Feb. 24, 2015; U.S. Pat. No. 9,018,958, issued Apr. 28, 2015; U.S. Pat. No. 9,052,366, issued Jun. 9, 2015; U.S. Pat. No. 9,201,120, issued Dec. 1, 2015; U.S. Pat. No. 9,229,062, issued Jan. 5, 20126; U.S. Pat. No. 9,244,100, issued Jan. 26, 2016; U.S. Pat. No. 9,255,955, issued Feb. 9, 2016; U.S. Pat. No. 9,274,157, issued Mar. 1, 2016; U.S. Pat. No. 9,312,575, issued Apr. 12, 2016; U.S. Pat. No. 9,335,362, issued May 10, 2016; U.S. Pat. No. 9,425,487, issued Aug. 23, 2016; U.S. Pat. No. 9,419,311, issued Aug. 16, 2016; U.S. Pat. No. 9,496,720, issued Nov. 15, 2016; U.S. Pat. No. 9,588,185, issued Mar. 7, 2017; U.S. Pat. No. 9,923,289, issued Mar. 20, 2018; U.S. Pat. No. 9,966,676, issued May 8, 2018; U.S. Pat. No. 10,046,649, issued Aug. 14, 2018; U.S. Pat. No. 10,222,397, issued Mar. 5, 2019; U.S. Pat. No. 10,317,468, issued Jun. 11, 2019; U.S. Pat. No. 10,429,449, issued Oct. 1, 2019; U.S. Pat. No. 10,473,555, issued Nov. 12, 2019; U.S. Pat. No. 10,608,353, issued Mar. 31, 2020; U.S. Pat. No. 10,843,574, issued Nov. 24, 2020; U.S. Pat. No. 11,054,480, issued Jul. 6, 2021; U.S. Pat. No. 11,325,479, issued May 10, 2022; U.S. Pat. No. 11,474,153, issued Oct. 18, 2022; U.S. Pat. No. 11,486,930, issued Nov. 1, 2022; U.S. Pat. No. 11,513,160, issued Nov. 29, 2022; U.S. Pat. No. 11,545,839, issued Jan. 3, 2023; U.S. Pat. No. 11,548,404, issued Jan. 10, 2023; U.S. Pat. No. 11,566,972, issued Jan. 31, 2023; U.S. Pat. No. 11,650,259, issued May 16, 2023; U.S. Pat. No. 11,668,779, issued Jun. 6, 2023; U.S. Pat. No. 11,740,294, issued Aug. 29, 2023; U.S. Pat. No. 11,926,224, issued Mar. 12, 2024; U.S. Pat. No. 11,973,202, issued Apr. 30, 2024; U.S. Ser. No. 09/780,146, filed Feb. 9, 2001, entitled STORAGE BATTERY WITH INTEGRAL BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERIES/PARALLEL SYSTEMS; U.S. Ser. No. 09/880,473, filed Jun. 13, 2001; entitled BATTERY TEST MODULE; U.S. Ser. No. 10/109,734, filed Mar. 28, 2002, entitled APPARATUS AND METHOD FOR COUNTERACTING SELF DISCHARGE IN A STORAGE BATTERY; U.S. Ser. No. 10/263,473, filed Oct. 2, 2002, entitled ELECTRONIC BATTERY TESTER WITH RELATIVE TEST OUTPUT; U.S. Ser. No. 09/653,963, filed Sep. 1, 2000, entitled SYSTEM AND METHOD FOR CONTROLLING POWER GENERATION AND STORAGE; U.S. Ser. No. 10/174,110, filed Jun. 18, 2002, entitled DAYTIME RUNNING LIGHT CONTROL USING AN INTELLIGENT POWER MANAGEMENT SYSTEM; U.S. Ser. No. 10/258,441, filed Apr. 9, 2003, entitled CURRENT MEASURING CIRCUIT SUITED FOR BATTERIES; U.S. Ser. No. 10/681,666, filed Oct. 8, 2003, entitled ELECTRONIC BATTERY TESTER WITH PROBE LIGHT; U.S. Ser. No. 11/207,419, filed Aug. 19, 2005, entitled SYSTEM FOR AUTOMATICALLY GATHERING BATTERY INFORMATION FOR USE DURING BATTERY TESTER/CHARGING, U.S. Ser. No. 11/356,443, filed Feb. 16, 2006, entitled ELECTRONIC BATTERY TESTER WITH NETWORK COMMUNICATION; U.S. Ser. No. 12/697,485, filed Feb. 1, 2010, entitled ELECTRONIC BATTERY TESTER; U.S. Ser. No. 12/769,911, filed Apr. 29, 2010, entitled STATIONARY BATTERY TESTER; U.S. Ser. No. 13/152,711, filed Jun. 3, 2011, entitled BATTERY PACK MAINTENANCE FOR ELECTRIC VEHICLE; U.S. Ser. No. 14/039,746, filed Sep. 27, 2013, entitled BATTERY PACK MAINTENANCE FOR ELECTRIC VEHICLE; U.S. Ser. No. 14/565,589, filed Dec. 10, 2014, entitled BATTERY TESTER AND BATTERY REGISTRATION TOOL; U.S. Ser. No. 15/017,887, filed Feb. 8, 2016, entitled METHOD AND APPARATUS FOR MEASURING A PARAMETER OF A VEHICLE ELECTRICAL SYSTEM; U.S. Ser. No. 15/049,483, filed Feb. 22, 2016, entitled BATTERY TESTER FOR ELECTRIC VEHICLE; U.S. Ser. No. 15/077,975, filed Mar. 23, 2016, entitled BATTERY MAINTENANCE SYSTEM; U.S. Ser. No. 15/149,579, filed May 9, 2016, entitled BATTERY TESTER FOR ELECTRIC VEHICLE; U.S. Ser. No. 16/253,526, filed Jan. 22, 2019, entitled HIGH CAPACITY BATTERY BALANCER; U.S. Ser. No. 17/364,953, filed Jul. 1, 2021, entitled ELECTRICAL LOAD FOR ELECTRONIC BATTERY TESTER AND ELECTRONIC BATTERY TESTER INCLUDING SUCH ELECTRICAL LOAD; U.S. Ser. No. 17/504,897, filed Oct. 19, 2021, entitled HIGH CAPACITY BATTERY BALANCER; U.S. Ser. No. 17/750,719, filed May 23, 2022, entitled BATTERY MONITORING SYSTEM; U.S. Ser. No. 17/893,412, filed Aug. 23, 2022, entitled POWER ADAPTER FOR AUTOMOTIVE VEHICLE MAINTENANCE DEVICE; U.S. Ser. No. 18/166,702, filed Feb. 9, 2023, entitled BATTERY MAINTENANCE DEVICE WITH HIGH VOLTAGE CONNECTOR; U.S. Ser. No. 18/314,266, filed May 9, 2023, entitled ELECTRONIC BATTERY TESTER, U.S. Ser. No. 18/324,382, filed May 26, 2023, entitled STACKABLE BATTERY MAINTENANCE SYSTEM, U.S. Ser. No. 18/328,827, filed Jun. 5, 2023, entitled ELECTRIC VEHICLE BATTERY STORAGE VESSEL; U.S. Ser. No. 18/337,203, filed Jun. 19, 2023, entitled HIGH USE BATTERY PACK MAINTENANCE; U.S. Ser. No. 18/609,344, filed Mar. 19, 2024, entitled INTELLIGENT MODULE INTERFACE FOR BATTERY MAINTENANCE DEVICE; U.S. Ser. No. 18/616,458, filed Mar. 26, 2024, entitled EV BATTERY CHARGING SOLUTION FOR CONTAINERS; U.S. Ser. No. 18/740,030, filed Jun. 11, 2024; all of which are incorporated herein by reference in their entireties.

### SUMMARY

A plurality of automotive tools is provided and each of which includes communication circuitry which provides communication between at least another tool in the plurality of tools. Cluster forming circuitry is configured to form a cluster comprising at least two tools in the plurality of tools. Each of the plurality of tools has at least one capability. Data sharing circuitry is configured to share data between the at least two tools in the cluster such that use of the at least one capability is shared between the at least two tools in the cluster.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 is a simplified block diagram of an example configuration of a tool or measurement device for performing a mesh cluster and testing various aspects of an automotive vehicle.

FIG. 2 is a simplified diagram showing additional details of the device of FIG. 1.

FIG. 3 is a diagram illustrating a virtual cluster formed in a mesh using three different tools which communicate over the internet to a reporting and management portal.

FIG. 4 shows resource advertisement by three tools in a virtual cluster.

FIG. 5 shows a diagram illustrating the selection of various resources within tools of the mesh cluster.

FIG. 6 shows a diagram illustrating the selection of various resources within tools of the mesh cluster.

FIG. 7 is a diagram showing three inspection lanes in a testing facility with each of the inspection lanes including three distinct tools.

FIGS. 8A and 8B illustrate resource sharing between tools in different mesh clusters.

### DETAILED DESCRIPTION

Embodiments of the present disclosure are described more fully hereinafter with reference to the accompanying drawings. Elements that are identified using the same or similar reference characters refer to the same or similar elements. Some elements may not be shown in each of the figures in order to simplify the illustrations.

The various embodiments of the present disclosure may be embodied in many different forms and should not be construed as limited to the specific embodiments set forth herein. Rather, these embodiments are provided so that this disclosure will be thorough and complete, and will fully convey the scope of the present disclosure to those skilled in the art.

Various types of vehicle maintenance equipment, including battery maintenance equipment, are used in commercial and government settings in which more than one such maintenance device is present. For example, a vehicle maintenance center may have multiple types of maintenance devices. Such devices include, for example, devices used to charge batteries, test batteries, read back diagnostic codes from a vehicle, check tire inflation, check aspects of the electric drive train, check other control systems within the vehicle, check operation of the motor and drive train of the vehicle, monitor safety related aspects of the vehicle including electrical short circuits, faulty grounds, failing connections or insulation, receive or send user input or output, provide wired or wireless communication, provide a printed output, store data, provide data analysis, etc. Similarly, in some jurisdictions, the local state or federal regulators require vehicle safety inspections in which multiple maintenance devices are present for use in determining the safety of operating a vehicle. This safety inspection can be used to verify that the vehicle is safe for operation in order for the vehicle to be certified for commercial sale or operation on public roads.

In such maintenance facilities, typically one or more operators or technicians perform various tests or other maintenance on a vehicle. The results of the test or maintenance operations can be recorded for use in determining a condition of a vehicle and either used locally or transmitted to another location. However, in such a configuration, efficient use is not made of the capabilities of all of the various maintenance devices that are present. For example, some devices may have duplicate functionality which is not necessary. Similarly, other devices may have limited functionality, requiring additional steps to be performed by an operator. These deficiencies and redundancies increase the cost of the overall maintenance facility and increase the amount of time required to perform maintenance on a vehicle. The present invention provides an implementation which addresses the shortcomings of the prior art configurations of such maintenance facilities to thereby increase efficiency of the vehicle maintenance process as well decrease the time required to perform such maintenance and decrease the cost to implement the maintenance facility.

With the present invention, a mesh network (or “cluster”) is created which comprises a plurality of distinct vehicle maintenance devices. Each maintenance device communicates information related to its capabilities, and the mesh system logic determines priorities of individual maintenance devices based upon each device's capabilities. The capabilities of the various devices include both the test that a particular device is able to perform as well as other capabilities including communication capabilities such as local communication or distant communication through the internet or other communication techniques, user I/O capabilities including input techniques and methods along with display and other output techniques, the capability of outputting a physical report using a printer, other types of input including an optical scanned or the capability of connecting to the databus of the vehicle, etc. Further, another example of a capability of a vehicle maintenance device is the amount of computing power and/or the amount of a storage a device has, including both permanent and volatile storage. Based upon these capabilities, a hierarchy of the various maintenance devices is determined, and a mesh type configuration between the devices in implemented, typically using a wireless communication technique between the various maintenance devices. However, in some configurations, one or more such maintenance devices communicate over a physical wired connection. If a mesh is formed that includes a physical connection, various physical aspects of such devices can be shared, for example, one device can provide power to a second device.

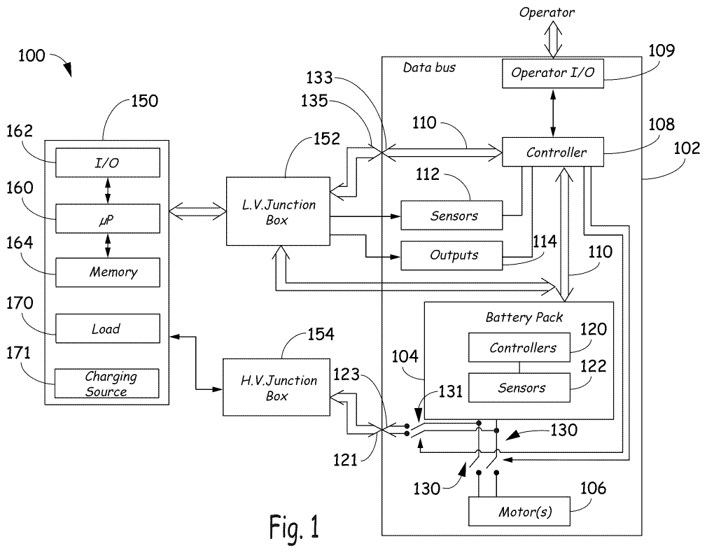

FIG. 1 is a simplified block diagram showing maintenance/diagnostic device 100 coupled to an electric vehicle 102. Device 100 is illustrated in a general way as a type of device used in the mesh configuration at a maintenance facility in accordance with one example configuration of the invention. The vehicle 102 is illustrated in a simple block diagram and includes a battery pack 104 used to power the vehicle 102 including providing power to motor(s) 106 of the vehicle. The vehicle 102 includes a vehicle controller 108 coupled to a databus 110 of the vehicle. The controller 108 receives information regarding operation of the vehicle through sensors 112 and controls operation of the vehicle through outputs 114. Further, the battery pack 104 is illustrated as including its own optional controller 120 which monitors operation of the battery pack 104 using battery pack sensors 122.

During operation, the electric vehicle 102 is controlled by the controller 108, for example, based upon input from a driver through operator I/O 109. Operator I/O 109 can comprise, for example, a foot accelerator input, a brake input, an input indicating a position of a steering wheel, information related to a desired gearing ratio for a drive train, outputs related to operation of the vehicle such as speed, charging information, amount of energy which remains in the battery pack 104, diagnostic information, etc. The controller 108 can control operation of the electric motors 106 to propel the vehicle, as well as monitor and control other systems of the vehicle 102. The controller 120 of battery pack 104 can be used to monitor the operation of the battery pack 104. For example, the sensors 122 may include temperature sensors configured to disconnect the batteries of the battery pack if a threshold temperature is exceeded. Other example sensors include current or voltage sensors, which can be used to monitor charge of the battery pack 104. FIG. 1 also illustrates contactor relays 130 of the vehicle 102 which are used to selectively decouple the battery pack 104 from systems of the vehicle 102 as discussed above. For example, the controller 108 can provide a signal to cause the contactors 130 to close, thereby connecting the battery pack 104 to electrical systems of the vehicle 102.

Device 100 includes a main unit 150 which couples to the vehicle through a low voltage junction box 152 and a high voltage junction box 154. These junction boxes 152, 154 are optional and other techniques may be used for coupling the maintenance device 100 to the vehicle 102. Maintenance device 100 includes a microprocessor 160, I/O circuitry 162 and memory 164 which contains, for example, programming instructions for use by microprocessor 160. The I/O circuitry 162 can be used to both user input, output, remote input, output as well as input and output with vehicle 102. The maintenance device 100 includes a controllable load 170 for use in discharging the battery pack 104. An optional charging source 171 is also provided and can be used in situations in which it is desirable to charge the battery pack 104, for example, to perform maintenance on the battery pack 104. The high voltage junction box 154 is used to provide an electrical connection between terminals of the battery pack 104 and the maintenance device main unit 150. Using this connection, batteries within the battery pack 104 can be discharged using the load 170 or charged using the charging source 171. Similarly, low voltage junction box 152 is used by battery pack maintenance device 100 to couple to low voltage systems of the electric vehicle 102. Such systems include the databus 110 of the vehicle, sensors 112, outputs 114, etc. Through this connection, as discussed above, the maintenance device 100 can gather information regarding the condition of systems within the vehicle 102 including the battery pack 104, and can control operation of systems within the vehicle 102. Similarly, through this connection, the outputs from sensors 112 can be changed or altered whereby altered sensor outputs can be provided to controller 108. This can be used, for example, to cause controller 108 to receive information indicating that the vehicle 102 or battery pack 104 is in a condition which is different than from what the sensors 112 are actually sensing. For example, this connection can be used to cause the contactors 130 to close to thereby provide an electrical connection to the battery pack 104. Further, the low voltage junction box 152 can be used to couple to the controller 120 and/or sensors 122 of the battery pack 104. The junction boxes 152, 154 couple to vehicle 102 through the use of an appropriate connector. The particular connector which is used can be selected based upon the specific type of vehicle 102 and the type of connections which are available to an operator. For example, OBD II connection can be used to couple to the databus 110 of the vehicle. Other plugs or adapters may be used to couple to sensors 112 or outputs 114. A particular style plug may be available for coupling the high voltage junction box 154 to the battery pack 104. If there are no contactors which are available or if they cannot be accessed or are unresponsive, in one configuration clips or other types of clamp on or selectively connectable contactors can be used to perform the coupling.

Vehicle 102 includes a data port 133, such as an OBD II port. This allows device 100 co communication with a databus of the vehicle. In such a configuration, a data connector 135 is provided for connecting to data port 133.

In one configuration, the high voltage connection to the vehicle is made through the vehicle charging port 123 and the device 00 includes a charging plug 121 of the appropriate configuration. The vehicle 102 includes additional contactors 131 which are used to selectively couple the battery pack 104 to the charging port 123. Some charging ports also include a data connection. In such a configuration, data port 133 can be included with charging port 123. Further, some configurations allow the transmission of data over the same wires used to provide the charging connection.

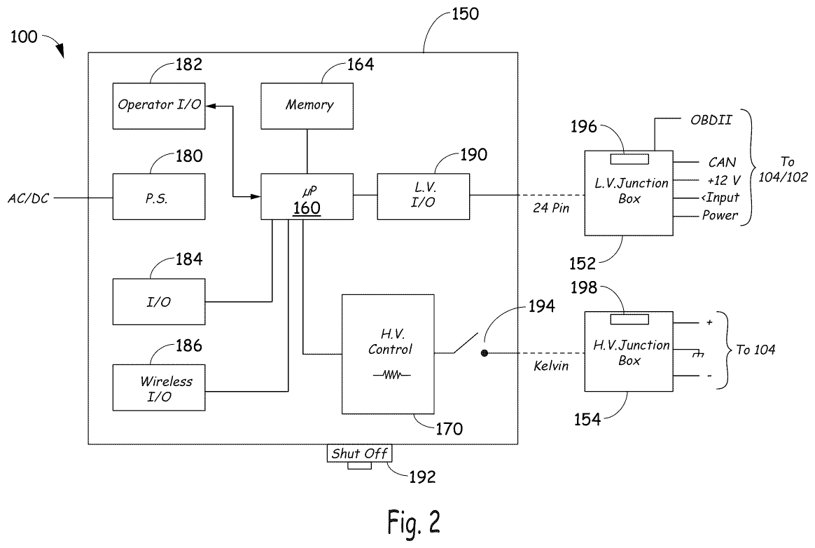

FIG. 2 is a simplified block diagram of a battery pack maintenance device 100 in accordance with one example embodiment of the present invention. The device includes a microprocessor 160 which operates in accordance with instructions stored in a memory 164 and can be used to implement the mesh system logic. A power supply is used to provide power to the device. The power supply 180 can be coupled to an AC power source, such as a wall outlet or other high power source, for use in charging the battery pack 104 of the vehicle 102. Additionally, the power supply 180 can be coupled to a DC power source, such as a 12 Volt battery, if the device 100 is only used for discharging of the vehicle battery pack 104. For example, in addition to the battery pack 104, many electric vehicles also include a standard 12 Volt automotive battery. This 12 Volt automotive battery can be used to power maintenance device 100. The microprocessor communicates with an operator using an operator input/output 182. Other input/output circuitry 184 is provided for use in physically connecting to a data communication link such as an RS232, USB connection, Ethernet, etc. An optional wireless I/O circuit 186 is also provided for use in communicating in accordance with wireless technologies such as Wi-Fi techniques, Bluetooth®, Zigbee®, etc. Low voltage input/output circuitry 190 is provided for use in communicating with the databus of the vehicle 108, the databus of the battery pack 104, or receiving other inputs or providing outputs to the vehicle 102. Examples include the CAN communication protocol, OBDII, etc. Additionally, contact closures or other voltage inputs or outputs can be applied to the vehicle using the low voltage I/O circuitry 190. FIG. 2 also illustrates an operator shut off switch 192 which can be activated to immediately disconnect the high voltage control 170 from the battery 104 using disconnect switch 194. Other circuit configurations can be used to implement this shut off capability. This configuration allows an operator to perform an emergency shut off or otherwise immediately disconnect the device 100 from the battery if desired.

The low voltage junction box 152 also provides an optional power output. This power can be used, for example, to power components of the vehicle 102 if the vehicle 102 has lost power. This can be useful, for example, to provide power to the controller 108 of the vehicle 102 such that information may be gathered from the vehicle and various components of the vehicle can be controlled such as the contactors 130.

In one configuration, the connection between the high voltage control circuitry 170 and the high voltage junction box 154 is through Kelvin type connectors. This can be used to eliminate the voltage drop which occurs when large currents are drawn through wiring to thereby provide more accurate voltage measurements. The actual connection between the junction box 154 and the battery pack 104 need not be through a Kelvin connection if the distance between the junction box 154 and the battery pack 104 is sufficiently short for the voltage drop across the connection leads to be negligible. Isolation circuitry such as fuses may be provided in the junction box 154 to prevent the application of a high voltage or current to the maintenance device 100 and thereby protect circuitry in the device. Similarly, the low voltage junction box 152 and/or the low voltage I/O 190 may include isolation circuitry such as optical isolators, inductors to provide inductive coupling, or other techniques. The low voltage junction box 152 may also include an optional user output and/or input 196. For example, this may be a display which can be observed by an operator. An example display includes an LED display, or individual LEDs, which provides an indication to the operator regarding the functioning of the low voltage junction box, the vehicle, or the battery pack. This can be used to visually inform an operator regarding the various functions being performed by the low voltage junction box, voltages detected by the low voltage junction box. A visual output and/or input 198 can be provided on the high voltage junction box 154.

The appropriate high voltage junction box 154 and low voltage junction box 152 can be selected based upon the particular vehicle 102 or battery pack 104 being inspected. Similarly, the junction boxes 152, 154 can be selected based upon the types of connections which are available in a particular situation. For example, if the vehicle his damaged, it may be impossible to couple to the battery pack 104 through available connectors. Instead, a junction box 154 can be employed which includes connection probes which can be coupled directly to the battery pack 104. Further still, if such a connection is not available or is damaged, connectors can be provided for coupling to individual cells or batteries within the battery pack 104.

The use of the low voltage and high voltage junction boxes 152, 154 are advantageous for a number of reasons. The junction boxes can be used to provide a standardized connection to the circuitry of the maintenance device 100. From a junction box 152, 154, specialized connectors can be provided for use with different types of vehicles and/or battery packs. Similarly, different types of junction boxes 152, 154 can be utilized for different vehicles and/or battery packs. The junction boxes 152, 154 allow a single set of cable connection to extend between the device 100 and a remote location. This provides better cable management, case of use, and increased accuracy.

In addition to use as a load for discharging the battery, the high voltage control circuitry may also optionally include a charging for use in charging the battery.

When the device 100 is coupled to a vehicle 102 which has been in an accident, the device can perform various tests on the vehicle 102 to determine the condition of the vehicle and the battery. For example, in one aspect, the device 100 detects a leakage between the positive and negative terminals of the battery pack 102 and the ground or chassis of the vehicle 102.

During discharging of the vehicle battery pack 104, data can be collected from the battery pack. For example, battery packs typically include sensors 122 such as voltage, current and temperature sensors arranged to collect data from various locations within the battery pack. This information can be obtained by the maintenance device 100 via the coupling to the databus 110. During discharge, any abnormal parameters measured by the sensors can be used to control the discharge. For example, if the battery pack 104 is experiencing excessive heating, the discharge rate can be reduced until the battery temperature returns to an acceptable level. If any of the internal temperature sensors of the battery pack are not functioning, an external battery pack temperature sensor can be used to detect the temperature of the battery pack. Similarly, if cells within the pack are experiencing an abnormally high current discharge, the discharge rate can be reduced. Further still, if such data cannot be obtained because the sensors are damages or the databus is damaged or inaccessible; the maintenance device 100 can automatically enter a slow/safe discharge state to ensure that the battery is not damaged.

Some electrical vehicles include what is referred to as a “pre-charge contactor.” The pre-charge contactor can be used to charge capacitances of the vehicle at a slow and controlled rate prior to switching in the main contactor 130 shown in FIG. 1. This prevents excessive current discharge from the battery pack when the main contactor is activated and the pack is directly coupled to the loads of the vehicle, including the traction module of the vehicle which is used to control electric motors of the vehicle.

In another aspect, some or all of the information obtained during testing is retrieved and stored, for example, in the memory 164 shown in FIG. 1, for subsequent access. This information can be offloaded to another device, for example a USB drive or the like, or transmitted over a network connection. The information can be information which is downloaded from the controller 108 of the vehicle 102 and may also be information related to how the vehicle battery pack 104 was discharged and removed of service.

In one configuration, the voltage sensor 232 is used to detect leakage currents in the battery undergoing discharge. The device can also monitor battery cell voltages and temperatures to ensure that unsafe conditions are not being created during discharge.

The input/output circuitry 190 can be used to connect to a databus of the vehicle, for example, through an OBDII connection in order to collect information such as VIN, software and hardware version numbers, etc. The device can communicate with the battery ECU (Electronic Control Unit) using any appropriate protocol including CAN, LIN, or others, in order to obtain specific battery information and discharge protocols. The device can be connected as a slave unit to another piece of shop equipment, either using a hardwired connection or a wireless connection such as Bluetooth or Wi-Fi. Reverse polarity protection as well as overvoltage protection can be provided. Other safety techniques for electrical potential, temperature and axis points can be fully interlocked to prevent operation of the unit. In one configuration, the input/output 184 can include a barcode scanner which can then be used to capture specific information such as battery type or serial number as well as vehicle identification number, etc. In another example configuration, input/output circuitry 184 can include a remote temperature sensor that can be electrically coupled to the discharger to report battery temperature. This is useful when internal battery temperature sensors are damaged or inoperative. The devices are scalable such that multiple controllable loads 100 can be connected in parallel. Relay contacts can also be provided and available externally to control various circuits on the battery pack undergoing discharge. Additional voltage sensing connections such as those provided by junction box 152 can be used to monitor various circuits on the battery pack.

Another example configuration includes a high voltage DC to DC converter such as power supply 180 shown in FIG. 2. In such a configuration, the high voltage output from the battery pack can be converted to a lower DC voltage for use in powering the device.

As discussed above, in some configurations the present invention can be arranged to measure a dynamic parameter of an electrical component of the vehicle. In such a configuration, a forcing function is applied to electrical components and a dynamic parameter such as dynamic conductance, resistance, admittance, etc. can be determined based upon a change in the voltage across the battery pack and the current flowing through the battery pack. The forcing function can be any type of function which has a time varying aspect, including an AC signal or a transient signal.

Different types of junction boxes and connection cables can be used based upon the particular type of vehicle and battery pack under maintenance. The microprocessor can provide information to the operator, prompting the operator to use the appropriate junction box or cable. This can be based upon the operator inputting the vehicle identification number (VIN) to the microprocessor, or other identifying information, including an identification number associated with the battery pack. During discharging of the battery pack, the microprocessor can also provide information to the operator which indicates the time remaining to complete the discharge. The microprocessor 160 can also detect if the correct junction box and cable have been coupled to the device and to the battery pack for the particular battery pack and vehicle under maintenance. Information can be provided to the operator if the wrong cabling or junction box has been employed.

As discussed above, the device 100 can include multiple connectors for use in connecting the low voltage junction box 152 and/or the high voltage junction box 154 to the vehicle 102 and/or battery pack 104. This allows the device 100 to easily be modified to interact with different types of batteries or vehicles by simply selecting the appropriate connector. In one configuration, the connectors include some type of identifier which can be read by the device 100 whereby the microprocessor 160 and device 100 can receive information to thereby identify the type of connector in use. This allows the microprocessor 100 to know what types of information or tests may be available through the various connectors. In another example, the operator uses operator I/O 182 shown in FIG. 2 to input information to the microprocessor 160 related to the type of connector(s) being used. In another example embodiment, the microprocessor 160 may receive information which identifies the type of vehicle or battery on which maintenance is being performed. This information can be input by an operator using the operator I/O 182 or through some other means such as by communicating with the databus of the vehicle, scanning a barcode or other type of input, etc. Based upon this information, the microprocessor can provide an output to the operator using operator I/O 182 which informs the operator which type of interconnect cable should be used to couple the low voltage junction box 152 and/or the high voltage junction box 154 to the vehicle and/or battery pack.

The operator I/O 182 may include a display along with a keypad input or touchscreen. The input may take various formats, for example, a menu driven format in which an operator moves through a series of menus selecting various options and configurations. Similarly, the operator I/O 182 can be used by the microprocessor 160 to step the operator through a maintenance procedure. In one configuration, the memory 164 is configured to receive a user identification which identifies the operator using the equipment. This can be input, for example, through operator I/O 182 and allows information related to the maintenance being performed to be associated with information which identifies a particular operator. Additional information that can be associated with the maintenance data include tests performed on the vehicle and/or battery, logging information, steps performed in accordance with the maintenance, date and time information, geographical location information, environmental information including temperature, test conditions, etc., along with any other desired information. This information can be stored in memory 164 for concurrent or subsequent transmission to another device or location for further analysis. Memory 164 can also store program instructions, battery parameters, vehicle parameters, testing or maintenance information or procedures, as well as other information. These programming instructions can be updated, for example, using I/O 184 or 186, through a USB flash drive, SD card or other memory device, or through some other means as desired. This allows the device 100 to be modified, for example, if new types of vehicles or battery pack configurations are released, if new testing or maintenance procedures are desired, etc.

As discussed herein, the maintenance device 100 can be used for testing safety related aspects of the vehicle 102. The low voltage connection 152 can couple to the databus of the vehicle, such as through an OBD II connection or the low voltage connection of the charging input, and the high voltage connection can couple to various points in the vehicle power train through a connector or a probe, or to the high voltage connection of the vehicle charging input. When testing a vehicle for safety relating aspects, an initial assumption can be made that the vehicle is safe and a series of tests are run to determine if this assumption is incorrect. A series of tests are performed and if any test fails, the vehicle is determined to be unsafe. This is essentially a logical OR function. Any one of the tests which is failed can create questions regarding vehicle safety. The OR function can be divided into two categories: 1) data that the vehicle computer (or ECU, Electronic Control Unit) is aware of and can report, and 2) data that can be independently identified externally by the maintenance device 100. This can also be used to ensure that the safety determination is not biased. The output provides a “state of safety” or “SOS” of the vehicle.

The maintenance device 100 can operate as a scan tool connected to the data port of the vehicle. Any of the following are example parameters that can create questions regarding safety that warrant further investigation:
Absolute battery voltage below a given threshold.
Individual cell voltage below a given threshold.
Standard deviation of cell voltages above a given threshold.
[MAX-MIN] cell voltages above a given threshold.
Cell conductance below a certain value. Note that this may not be directly reported by ECU but can be calculated using virtual conductance techniques such a monitoring current through a cell and voltage across a cell.
Cell conductance standard deviation above a certain threshold.
Faults reported by the ECU.
Any cell not reporting data.
Any temperature sensor not reporting data.
Any current or voltage sensor not reporting.
Airbags were deployed.
Internal current leakage fault.
Other safety related PID (parameter ID) values.
   An external validation device, such as maintenance device 100:
Can report any current leakage value of a battery pack to the vehicle chassis resulting from one of the following:
Insulation breakdown or degradation
Electrolyte seepage
Burst cells
Mechanical breakdown of internal components
Contamination in battery pack
Seal failure
Water ingress
Structural damage to pack

Although some of these parameters can be measured with a scan tool, with the present invention a determination of safety based on the values, or combination of values is made, for example by microprocessor 160. The parameters can be processed by a rule set to arrive at a safety determination. In order to measure leakage current, device 100 can be coupled to a battery pole, for example the B+, B− MSD, or auxiliary ports of battery pack 104 and determine the impedance to ground at any other point in the circuit. With this measurement, it does not matter where the fault is relative to the test point. An adapter can be provided that is received in the CCS DC charge point, sending commands to close the contactors, and check from one of the poles. Although some battery packs have internal leakage circuits, they may be unreliable and will not suffice for safety inspections.

Another aspect of the invention relates to measuring electrical isolation of components. Isolation is conventionally measured by what is referred to as a HIPOT test, which stands for high potential. This is used to check the integrity of insulation systems, primarily on AC wiring. A voltage is selected that is some considerable factor above the working voltage of the system, and applied to each conductor relative to another component, such as the vehicle chassis. Ideally, there should be no conduction. However, in practice, there is always some form of a high resistance electrical pathway and the actual isolation will be greater than some selected number of megohms. It is considered a non-destructive test, in that the insulation is not damaged as a result of this test. The present invention includes checking the insulation of the AC charge port using either this method, or a small signal AC based forcing function.

For battery systems, regardless of the presence of any leakage path, the leakage is not visible to the test equipment unless the potential applied exceeds the battery string voltage. However, at this voltage level, the test is a destructive test. As such, this test of the safety of the insulation actually results in a degradation to the system. This is because of the sensitive nature of battery cells. They are not simple insulation systems, but complex systems with electrolyte, separators, electrodes, and other components. Exceeding a voltage across a cell causes breakdown of the separator, which leads to failure. This method is used during the manufacture of cells as a spot check of separator integrity, but those cells are discarded following the test procedure. For this scenario, a small signal AC forcing function can be used to detect the leakage without exceeding the battery voltage. The AC signal will pass through the cell, elevating both the anode and cathode simultaneously.

In one aspect, a small AC voltage at a low frequency is generated. The frequency can be chosen as desired, but preferably in the ELF (extremely low frequency) range. In specific configurations, 50 HZ or 100 HZ are used. However, other frequencies may be used as desired. This signal can be applied to a tuned circuit (voltage divider) and capacitively coupled the into the battery string. The output of the voltage divider is monitored between the divider and the coupling capacitor. When the circuit is “loaded” on the battery side due to the presence of isolation resistance, the test equipment monitors the degradation of the drive signal and can solve the resulting equation for the unknown isolation resistance. Further, this configuration is not sensitive to where the leakage is located within the high voltage string.

The measurement equipment can test the leakage of the available circuits, either through the charge port, or any other point in the system that allows access or an electrical probe or connection. This may be at the manual safety disconnect, which provides access to the individual halves or sections of the battery system. Other locations can be accessed, for example, through any high voltage accessory port, such as the AC compressor.

Vehicles generally have two types of charge ports: Those that accept AC power only (either single or 3 phase), or those that accept both AC and DC.

The measurement system can test all types of connections. The AC connections can be tested by either the AC signal method disclosed herein, or a conventional HIPOT test. The DC charging connection can only be tested using the AC signal model.

Electric vehicle charging connectors vary widely by manufacturer and location. One preferred connection is a standard unit with the NACS (North American Charging System) connector. This type of connector is preferred because it provides AC and DC connections, along with data communication, in a very small format. Adapters can be used that convert this to other connector standard such as J1772, CCS1, CCS2, or others. In another configuration, region specific units can be provided that have the appropriate connector built in. The main assembly is the same, but customized connectors can fit into a storage area in the housing of device 100.

Additionally, the AC or DC charge contactors 131 can be instructed to close. Communication can be achieved with the vehicle using, for example, the data connection when element 121 is configured as a charging plug. For example, the control pilot pin can be used to instruct contactors 131 to close. For example, using the HomePlug Green PHY protocol. Such configurations allow communication of data over a power connection.

There are vehicles which are equipped with vehicle-to-grid charging connection. In such a configuration, the vehicle does not expect to see a charger connected to the charging port and instead receives a line voltage AC input. However, most vehicles do not have this ability, in which case, the vehicle must be instructed to close the contactors without a charger present. One way which this can be implemented with some vehicles is simply to communicate to the vehicle computer indicating that there is a charger connected. Once the contacts close, there is no way for the vehicle to detect this because the vehicle sees the same voltage outside the car and inside the car because the voltages are all generated by the vehicle battery. Another technique that can be used to instruct the contactors to close is to generate a high voltage reference at a low current level (not enough to charge, but enough for the vehicle to read a voltage). Once the contactors close, they will remain closed.

Element 121 can be configured as an electrical connector configured to connect to various standard connectors of vehicle 102 such as connectors used to connect to battery pack 104, an internal DC to DC converter in vehicle 102, the charging port 123, or other components. Element 121 can also be configured as a probe such that an operator can manually touch the probe 121 to various locations in vehicle 102. For example, probe 121 can be used to probe various points along the string of batteries that make up battery pack 104. A display in operator I/O can be used to instruct an operator where to place the probe through written instructions and/or images.

In the automotive diagnostic and maintenance industry, various tools have private network connectivity options using various interface protocols such as Bluetooth®, Wi-Fi, Zigbee®, Thread/Matter, etc. These protocols, and others, allow the maintenance devices to communicate on local private networks. With the present invention, the devices can dynamically create clusters (with user input or preconfigured) for resource and data sharing as well as result correlation. Device 100 is an example implementation of a maintenance device configured in accordance with the invention.

With the present invention, a proprietary discovery and hierarchy protocol is executed on top of this network. This protocol allows the discovery of various capabilities across each device. Each maintenance device advertises its own unique identification and capabilities. This information is then shared with other devices in the cluster.

Once discovered, these devices can notify an operator using the user interface 182 or using a configuration algorithm so that they are added to the cluster. Based on the resources they advertise (e.g., memory, processor, UI, printer access, network/Internet access, scanner, etc.) as well as capabilities, these tools will be assigned a weight when joining the cluster. This algorithm can be stored in memory 164 and implemented in the microprocessor 160 of one or more of the devices which form the cluster.

Once this cluster is formed, the device 100 with the highest weight is elected/selected as the cluster master. This cluster master is responsible for managing the cluster and reporting which services and functionality are available inside this tool cluster.

Resources from each of the devices 100 in the cluster that are available are now a part of this cluster. Inputs accepted from the various devices 100, such as a VIN scan, an operator input etc., become a common identification (ID) for tests done by devices 100 within this cluster. This allows the user to only input data at a single shared user interface, which is then shared across all of the devices 100 in the cluster. The maintenance devices 100 report their interim results/data back to the cluster master.

Once all the tests pertaining to the single unit/vehicle are completed, the cluster master collates all the interim results. The master is then the responsible to upload the information to the information portal/endpoint (either processed or raw data) as desired.

This configuration if particularly useful due to the complexity of EV vehicles and management/validation of the battery/batteries. As EVs are becoming more common, the servicing and inspection of such vehicles is also becoming more complex, requiring multiple tools in workshops and inspections for regulatory bodies.

This invention applies to inspection/management/testing/validation of multiple aspects of battery (in vehicles with internal combustion engines or other legacy vehicles) or batteries (for EVs that have multiple batteries—High Voltage and Low Voltage) for various functions/controls.

When validating or managing batteries, multiple tools can be used either in sequence or in parallel when working on the vehicle. For example, low voltage tools can be used for validating the low voltage 12V battery, specifically for reserve charge, state of charge (SoC), state of health (SoH), and other parameters, to determine the capacity/health of the battery. While the high voltage tools can be used to validate other high voltage (HV) parameters related to the performance and/or safety of the HV battery pack which is used to power the vehicle.

In environments such as workshops and vehicle inspection facilities, it is desirable to minimize the required inputs and the time needed to work on a vehicle. In order to optimize the time required to service/inspect a vehicle with multiple tools, the invention provides a way to allow multiple tools to create a cluster of tools which are used for one vehicle, or used in a single inspection lane across multiple stations within the lane.

This cluster of maintenance devices is able to internally discover each other and notify an operator. The operator can then allow connectivity between the devices. Although the discovery is dynamic across multiple devices, a user input can optionally be required to allow formation of the cluster for security reasons as well as maintaining a hierarchy between the devices. The cluster can also be formed automatically if desired. Discovery of the devices is performed using available wireless protocols across the devices, for example, Bluetooth, Zigbee, Wi-Fi adhoc networks, etc., using wireless I/O 186. These devices create a private, secure network that allows them to advertise the resources available to each other such that the resources can be shared within the cluster. This enables resource sharing, for example, some tools may have an input device such as a scanner, QR code reader, etc., that may simplify user input by scanning the VIN/battery information from a battery or vehicle. Other tools may have resources such as a local/connected printer, internet connectivity to the cloud, certain test capabilities, etc.

Another aspect of this device cluster is that it enables the collating of results across the various tests performed by the devices into a single consolidated piece of data. This consolidates the data and the reporting of the data. This enables a better understanding of various results and also allows the correlation to identify parameters and the root cause of issues using causality of symptoms observed across various tests performed. In addition to the various tests discussed herein, element 152 can also comprise other types of testing apparatus such as a tire pressure tester, tread depth gage, compression tester, exhaust analyzer, voltage or current sensor, or other test or measurement device that are used with vehicles.

Once formed, this cluster becomes a single logical entity acting like a single instance of a maintenance device which has multiple test/measurement capabilities, although internally to the cluster, multiple tools are performing the various independent tests/measurements.

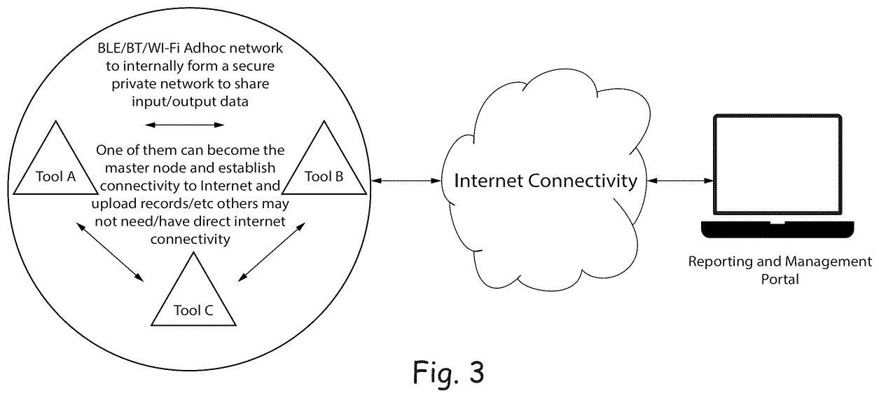

If one of the devices within the cluster goes offline, the device will be removed from the cluster after a timeout period. To detect the status of a device, the devices can periodically send heartbeat messages to the other devices in the cluster. Cluster membership is dynamic but, in some embodiments, can require an input from an operator to add or delete a device from the cluster. The cluster membership can also be pre-provisioned so that a certain set of devices are automatically allowed membership. Cluster master selection is also dynamic and can be based on capabilities/resources of the devices. If a master goes offline, a new master is selected from the other tools in the network within a finite amount of time. In another configuration, the cluster can be provisioned with a fixed master and the cluster then be dissolved if the master goes offline. FIG. 3 is a diagram of a virtual cluster formed by three tools A, B and C having internet connectivity to a central reporting or management portal.

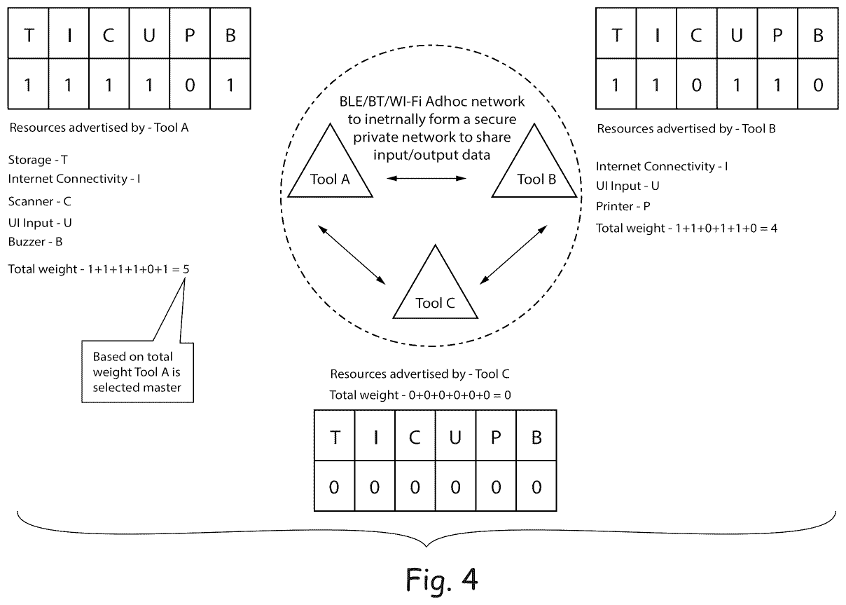

FIG. 4 is a diagram showing one example weighting configuration for use in forming a cluster of tools. In FIG. 4 each tool advertises its capabilities including storage (T), internet connectivity (I), the presence of a scanner (C), the presence of a user input (U), the presence of an audio output or buzzer (B), and the presence of a printer (P). In this configuration, the presence of any of these items is given a weight of one, however, different weighting factors can be used as desired. With this arrangement, tool A has a weight of 5, tool B has a weight of 4 and tool C has a weight of zero.

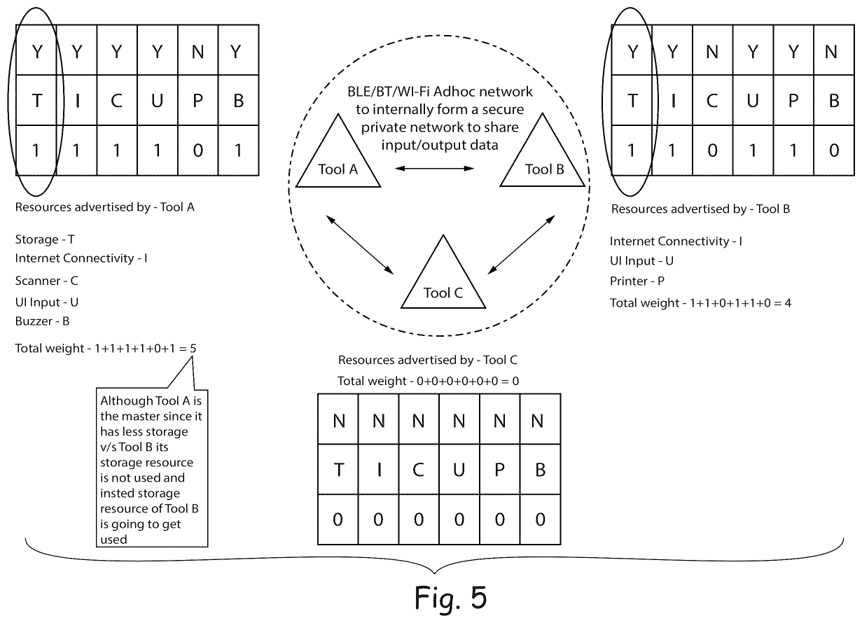

FIG. 5 is a diagram showing how resources are selected for use. In addition to advertising the presence of a particular capability, information related to that capability is also advertised. For example, if tool B has more storage than tool A, tool B can be selected as the device on which data is stored. Other capabilities can also be advertised with such ranking information. For example, one device might have a faster internet connection, a hard-wired network connection, a display versus a simple audio output, specific measurement capabilities, etc.

The configuration provides a dynamic private network cluster for battery tool resource management and sharing. This can be through a weighted mesh network. This is an enhancement to the existing mesh master/controller selection using a weighted algorithm where each resource is allocated a weight factor based on its usefulness in the cluster. For example, a display and keyboard interface is given a factor of 10 while a simple buzzer is allocated a factor of 1. So, in this example when the cluster starts assigning weights, the master is not selected only based on how many resources they contain (simple additions of 0 or 1), but based on which resources and the importance of the resource in the mesh.

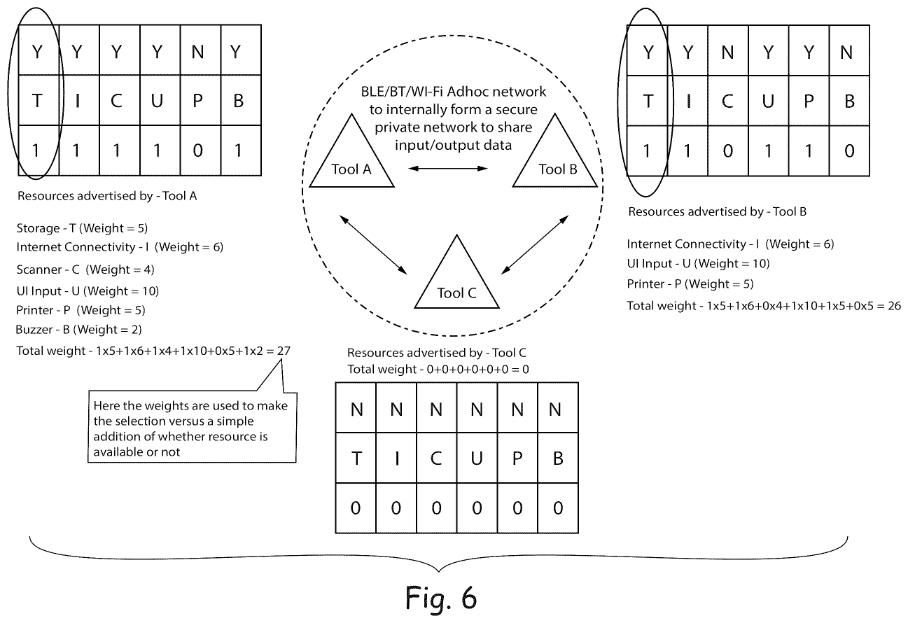

FIG. 6 shows another example of this capability advertisement: Each tool advertises its unique ID and capabilities (e.g., memory, processor, UI, printer access, network/Internet access, scanner). These capabilities are then weighted. The same mesh model is now updated as shown in FIG. 6.

In this configuration, weights are assigned to each capability, with more critical capabilities (e.g., Internet connectivity, VIN scanner) having higher weights.

The weights are assigned based on usefulness and importance of resources to the complete cluster.
1. Storage—T (Weight=5)
2. Internet Connectivity—I (Weight=6)
3. Scanner—C (Weight=4)
4. UI Input—U (Weight=10)
5. Buzzer—B (Weight=2)
6. Printer—P (Weight=5)

The tool with the highest combined weight is selected as the cluster master and is responsible for managing the cluster and coordinating tasks. Tools dynamically discover each other and notify the user for cluster formation. The tool with the highest weight becomes the master. If the master tool fails, another tool with the next highest weight takes over, ensuring continuity. In case of a tie in weights between two or more devices, additional criteria such as unique capabilities (e.g., printer, buzzer) are used to select the master.

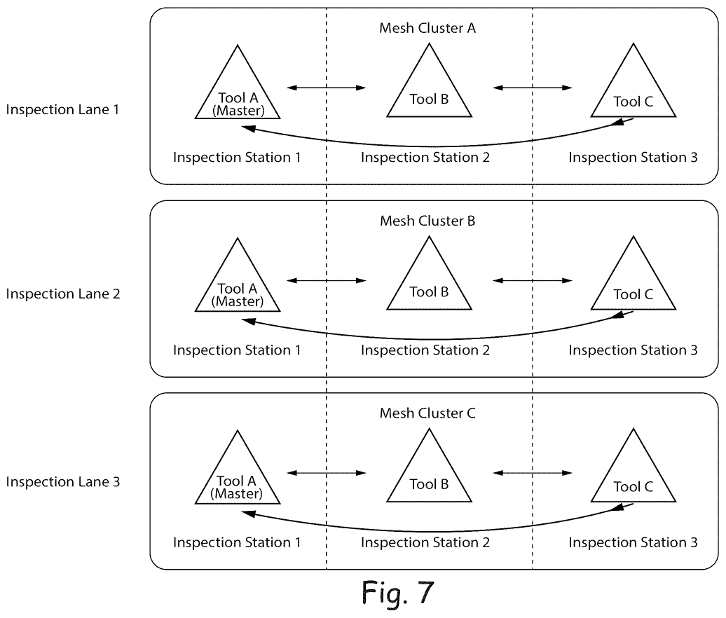

FIG. 7 shows three different tool types deployed across three inspection lanes in a vehicle inspection facility. A vehicle follows an inspection lane and goes from one station to another in a specific sequence, and a specific set of tests are run at each station. Here the tools may be the same or different, e.g. the same high voltage safety tool is used at station 1 as well as station 3, while another low voltage safety or immobilizer tool is used on station 2. Moreover, even if the same tool is used across multiple stations, for example at stations 1 and 3, station 1 may be only running 3 out of total 4 tests (immobilizer, AC touch current and AC insulation tests), while at station 3 there may be a lift available to access underside of the car such that an additional test can be performed.

In this scenario, the tools in a cluster must also maintain some sort of sequence when pairing, as the tools need to maintain the order which they are activated at which station or order in the specific sequence. And, until all the data is collected by the master controller, it cannot be uploaded. In this configuration, each tool is assigned an order/sequence ID in the cluster at the time of provisioning. For example, these tools are assigned a sequence as:
Tool A—S1 (Master based on above weights).
Tool B—S3
Tool C—S2

Tools in the inspection lane operate in a specific sequence (e.g., S1→S2→S3). However, as discussed above, since these tools have different capabilities, and the master is responsible for collating all the data from all the tests performed by A, B, C, only then once the tool B (sequence S3) is completed with its tests and has sent its results to the master can the master collates all the results internally and upload the data to the backend server through internet connectivity.

This sequence number assignment is a unique capability of this cluster provisioning to maintain the order of tests and results in an inspection facility. This may be also be used in cases such as dealer workshops or salvage yards where specific operations are done in a different order to either perform repairs and/or removal of components in salvage yards where the tools are used prior to harvesting various components of the cars like batteries, DC-DC converters, etc.

The master tool can be any tool in the sequence, but must ensure all data is gathered before sending records upstream. The master tool cannot send the recorded data until all information is gathered from each tool in the sequence. The dataset is marked complete only after the VIN scan and all data intake is finished.

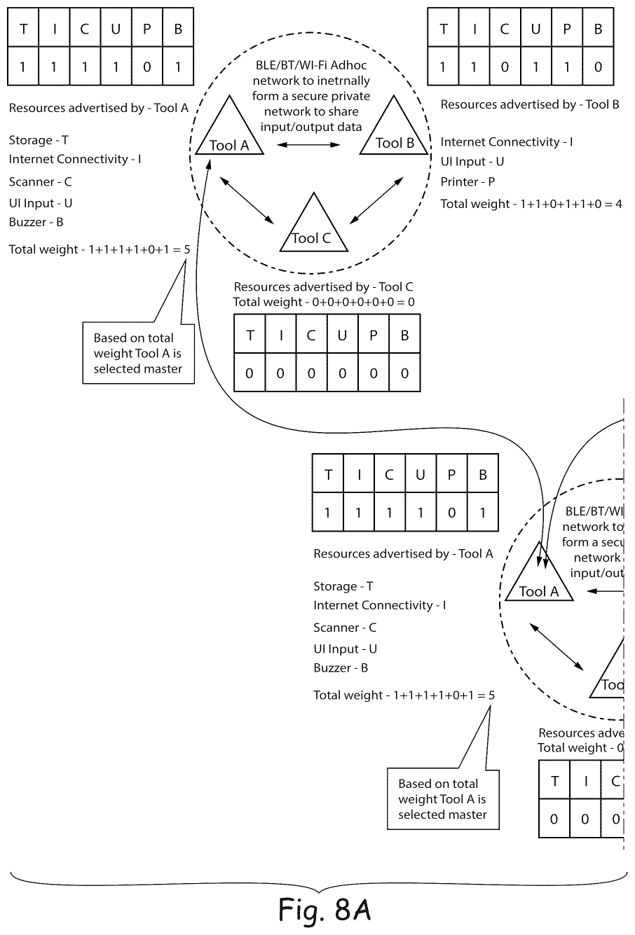

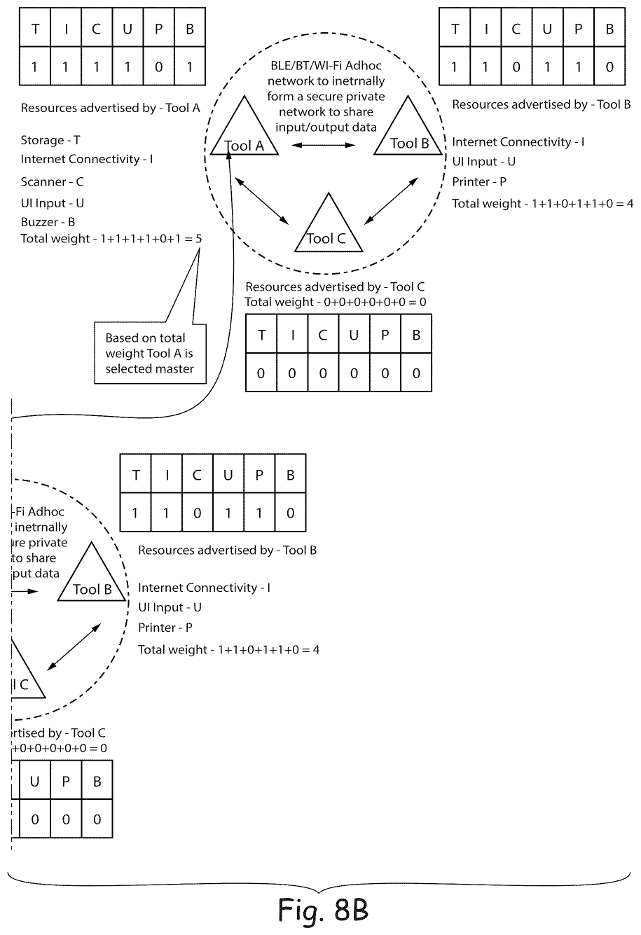

The configuration also provinces inter-cluster communication capabilities. Tools within a cluster can share resources. For example, a tool without a printer can use another tool's printer. This can be used for redundancy where there is a facility with multiple clusters of tools. Each cluster is identical but with a different instance of tools. If there is a need to share resources across clusters or mesh, then the masters across these meshes can communicate and share those resources, as illustrated in FIG. 8. Each cluster can communicate with the other clusters in the same deployment facility. For example, if each mesh is tied to an inspection lane and there are multiple inspection lanes in the same facility, then master controllers across clusters can communicate the health and other information such that if one cluster is impaired the other clusters get notified and can lend their resources to the impair cluster.

The master tool collects data from all tools and sends it upstream as a single record, ensuring seamless data integration and processing for analytics and archiving. Tools can be replaced and given the same identity to maintain the processing chain, ensuring new tools integrate smoothly without disrupting the workflow.

The system can include a mechanism for persistently storing the mesh configuration, for example, in memory 164 of the device. This ensures that the configuration details are retained even if the master tool is impaired or replaced. The mesh configuration is stored in a non-volatile memory within the master tool and optionally in a central server or cloud storage. The stored configuration can include details such as tool IDs, capabilities, weights, operational sequence information, and master selection criteria. This persistent storage allows for quick recovery and reconfiguration of the cluster in case of master tool failure.

Automatic configuration retrieval can also be implemented. When a new master tool is introduced to replace an impaired one, the system automatically retrieves the stored configuration. The new master tool accesses the non-volatile memory or central server to download the existing mesh configuration. The retrieved configuration is applied to the new master tool, ensuring seamless integration into the cluster. This process minimizes downtime and ensures continuity in the cluster's operation.

In another configuration, the system can periodically synchronize the mesh configuration across all tools in the cluster. Each tool in the cluster maintains a local copy of the mesh configuration. The master tool periodically updates the configuration to ensure consistency across the cluster. In the event of a master tool failure, the most recent configuration is readily available for the new master tool.

The system can also include a robust failover and recovery mechanism to handle the replacement of the master tool. Upon detecting the failure of the master tool, the system initiates the failover process. The tool with the next highest weight is selected as the new master. The new master tool retrieves the stored configuration and resumes the management of the cluster. This mechanism ensures that the cluster remains operational with minimal disruption.

The system can provide notification to the user in case of master tool failure and during the replacement process. This can be through operator I/O 182, or transmitter over the network. Users are notified of the master tool failure and the initiation of the failover process. The system provides instructions for introducing a new master tool and retrieving the stored configuration. User intervention is minimized, but the system allows for manual adjustments if necessary. For example:
1—Master Tool Failure: The current master tool (Tool A) fails during operation. The system detects the failure and initiates the failover process.
2—Selection of New Master Tool: The tool with the next highest weight (Tool B) is selected as the new master. Tool B retrieves the stored mesh configuration from the non-volatile memory or central server. In this case the mesh is not in a completely operational state as some of the resources are impacted but can still be partly functional
3—Configuration Application: Tool B applies the retrieved configuration, including tool IDs, capabilities, weights, and operational sequence. Tool B seamlessly integrates into the cluster and resumes management duties.
4—User Notification: The user is notified of the master tool failure and the successful replacement with Tool B. The system provides any necessary instructions for further actions, if required.
5—Replacement of Failed Tool: A new instance of Tool A (Tool A′) is introduced to replace the failed Tool A. Tool A′ automatically retrieves the stored mesh configuration from the non-volatile memory or central server. Tool A′ downloads and applies the stored configuration information, including tool IDs, capabilities, weights, and operational sequence.
6—Integration and Operation: Tool A′ integrates into the cluster, taking over the role and responsibilities of the original Tool A. The mesh/cluster becomes fully operational with minimal downtime, ensuring continuity in the inspection process.

The persistent storage and automatic retrieval of the mesh configuration ensure that the cluster remains operational with minimal downtime. The new master tool can quickly integrate into the cluster, maintaining continuity in operations. The failover and recovery mechanism enhances the overall reliability and robustness of the system. The system minimizes the need for user intervention, providing a seamless and user-friendly experience.

Once a cluster is configured and operational, its configuration can be saved. This saved configuration includes details such as tool IDs, capabilities, weights, and sequence. This feature allows for the replication of an established cluster configuration across multiple inspection lanes within a facility, ensuring identical setup without the need to redo the complete configuration process for each lane.

The logical cluster configuration, including its operational sequence and master tool selection criteria, can be cloned. This ensures that new lanes have the same tool setup and operational logic as the original cluster. Cloning is particularly useful in large inspection facilities with multiple lanes, ensuring consistency and efficiency across all lanes.

A dedicated module within the system handles the saving, downloading, and cloning of configurations. Users can access this module through a user-friendly interface to manage cluster configurations. This can be implemented in a separate controller 160. The module ensures that configurations are stored securely and can be easily retrieved, facilitating easy cloning of clusters for new lanes or facilities.

The system supports automated deployment, where users can select a saved configuration and deploy it to new lanes. The deployment process automatically configures all tools in the new lane according to the saved configuration. This feature reduces setup time and ensures consistency across lanes, minimizing errors in configuration.

The system is designed to be scalable, allowing for the addition of new lanes and tools. New lanes can be added by cloning existing clusters, ensuring seamless expansion. The system can accommodate additional tools and lanes as needed, maintaining flexibility and adaptability.

The system allows for the replication of cluster configurations across different facilities. This ensures that the same set of tools and operations can be maintained in different inspection facilities, even if they are located in different suburbs or regions. The saved configuration can be stored as a template and replicated across multiple facilities. Each facility can download and apply the template configuration, ensuring consistent tool setup and operational logic. This feature is particularly useful for organizations with multiple inspection facilities, allowing them to maintain uniformity and efficiency across all locations. For example:

Replication Across Facilities: The saved mesh configuration is stored as a template. A new inspection facility in a different suburb or region downloads the template configuration. The new facility applies the configuration, ensuring the same tool setup and operational logic as the original facility. This allows for consistent and efficient operations across multiple facilities.

The ability to replicate cluster configurations across different facilities ensures uniformity and efficiency in operations, regardless of location. Regulatory bodies can use this system for efficient and comprehensive vehicle inspections. OEMs and dealerships can use the system for servicing and maintaining vehicles. Companies providing aftermarket services for low and high voltage battery systems can benefit from this tool cluster.

A unique discovery protocol is implemented that allows tools to discover each other and advertise their capabilities dynamically. This ensures secure and efficient formation of clusters with user input for added security. The master tool manages the cluster, listing available services and coordinating tasks. This ensures that all tools work together seamlessly, even if they have different capabilities. Further, this ensures that data collected from all tools is accurate and securely transmitted to the upstream server. Uses encryption and secure communication protocols can be used to protect data integrity. A single shared UI for data input can be provided, reducing the need for multiple inputs and simplifying the user experience. This can be used to guide users through the testing process with clear instructions and feedback.

The system allows for the replication of an established cluster configuration across multiple inspection lanes within a facility. Once a cluster is configured and operational, its configuration can be saved. The saved configuration can be downloaded to form new instances of the cluster in different lanes. This eliminates the need to redo the complete configuration process for each lane.

The system supports cloning of logical clusters to create identical clusters in new inspection lanes. The logical cluster configuration, including tool sequence and capabilities, can be cloned. New lanes can be added by simply cloning the existing cluster configuration. Ensures consistency and efficiency across multiple inspection lanes.

The system includes a configuration management module that handles the saving, downloading, and cloning of cluster configurations. The configuration management module stores the cluster configurations. Provides an interface for users to save and download configurations. This facilitates easy cloning of clusters for new lanes or facilities.

The system supports automated deployment of clusters based on saved configurations. Users can select a saved configuration and deploy it automatically to new lanes. The system ensures that all tools in the new lane are configured identically to the original cluster. This reduces setup time and minimizes errors in configuration.

The system is scalable and flexible, allowing for the addition of new lanes and tools without disrupting existing clusters. New lanes can be added by cloning existing clusters. The system can accommodate additional tools and lanes as needed. This ensures seamless integration and scalability.

Although the present invention has been described with reference to preferred embodiments, workers skilled in the art will recognize that changes may be made in form and detail without departing from the spirit and scope of the invention. The invention is suitable for many configurations. For example, vehicle inspection centers (regulatory), original equipment manufacturers, servicing locations and dealership, and aftermarket vehicle/battery (both low voltage and high voltage) servicing. Various components of the invention can be implement in microprocessor/controller 160 operating in accordance with instructions stored in memory 164. For example, microprocessor/controller 160 and memory 164 can implement cluster forming circuitry used to form cluster among a plurality of tools and data sharing circuitry used to share data between tools. Wireless I/O 186 may also be configured as a wired connection in some configurations. Input/output circuitry 162/184 can provide any time of input or output, including a printer, a scanner, a camera, or other device. The cluster provides a dynamic mesh network in which tools can be added or removed from the cluster.

What is claimed is:

1. A plurality of automotive vehicle maintenance tools each of which includes:
communication circuitry which provides communication between at least another tool in the plurality of tools;
cluster forming circuitry configured to form a cluster of tools comprising at least two tools in the plurality of tools;
data sharing circuitry configured to share data between the at least two tools in the cluster of tools; and
wherein each of the plurality of tools in the cluster of tools has at least one operational capability and the at least one operational capability is shared with other tools in the cluster of tools using the data sharing circuitry.

2. The apparatus of claim 1 wherein each of the plurality of maintenance tools advertises its capabilities to other tools in the cluster of tools.

3. The apparatus of claim 2 wherein each advertised capability is given a weight.

4. The apparatus of claim 3 wherein in a master tool for the cluster of tools is selected based upon a highest total weight of capabilities.

5. The apparatus of claim 3 wherein a capability of a tool is selected to be shared based up a weight assigned to the capability.

6. The apparatus of claim 1 wherein a user input is required to add a tool to the cluster of tools.

7. The apparatus of claim 1 wherein the cluster of tools forms a lane in a testing facility.

8. The apparatus of claim 7 including a plurality of lanes each including a cluster of tools.

9. The apparatus of claim 8 wherein each of the cluster of tools includes a master tool.

10. The apparatus of claim 9 wherein master tools are configured to share data with a master tool in another cluster of tools.

11. The apparatus of claim 1 including memory configured to store a sequence of operation of tools in the cluster of tools.

12. The apparatus of claim 1 including memory configured to store configuration information related to the configuration of the cluster of tools.

13. The apparatus of claim 1 wherein the at least one operational capability relates to a testing capability.

14. The apparatus of claim 1 wherein the at least one operational capability relates to an input/output capability.

15. The apparatus of claim 1 wherein the at least one operational capability relates to a storage capability.

16. The apparatus of claim 1 wherein a tool can be removed from the cluster of tools.

17. The apparatus of claim 16 wherein a new tool can be added to the cluster of tools and receive information related to a configuration of the cluster.

18. The apparatus of claim 13 wherein the testing capability relates to testing a battery of an electric vehicle.

19. The apparatus of claim 1 wherein each tool in the cluster of tools includes identification information which is shared with other tools in the cluster of tools.
